(19) United States
(12) Patent Application Publication
(10) Pub. No.: US 2017/0265328 A1
(43) Pub. Date: Sep. 14, 2017

(54) ELECTRONIC EQUIPMENT

(71) Applicant: FUJITSU LIMITED, Kawasaki-shi (JP)

(72) Inventors: Yuta SASAKI, Kawasaki (JP); TAKASHI YAMAMOTO, Nerima (JP); Yuta Suzuki, Kawasaki (JP)

(73) Assignee: FUJITSU LIMITED, Kawasaki-shi (JP)

(21) Appl. No.: 15/453,238

(22) Filed: Mar. 8, 2017

(30) Foreign Application Priority Data
Mar. 11, 2016 (JP) 2016-047796

(51) Int. Cl. H05K 7/20

(52) U.S. Cl. CPC H05K 7/20236; H05K 7/20781; H05K 7/20272

(57) ABSTRACT

An electronic equipment includes a refrigerant tank that contains a refrigerant, a plurality of electronic components immersed in the refrigerant of the refrigerant tank, and a refrigerant injection member including a plurality of injection holes to inject the refrigerant supplied from a refrigerant inlet so as to cause the refrigerant to flow between the plurality of electronic components, wherein opening areas of the injection holes of the refrigerant injection member are set to be larger as the injection holes are far from the refrigerant inlet.

### CROSS-REFERENCE TO RELATED APPLICATION

This application is based upon and claims the benefit of priority of the prior Japanese Patent Application No. 2016-047796, filed on Mar. 11, 2016, the entire contents of which are incorporated herein by reference.

### FIELD

The embodiments discussed herein are related to a liquid immersion cooling type electronic equipment.

### BACKGROUND

There has been a growing demand for mounting electronic components such as, for example, storages with a high density, in a data center. In the meantime, a heating value of electronic components used in an electronic equipment is increasing with the implementation of the electronic equipment with high performance.

When the electronic components having a large heating value are mounted with high density, the temperature of the electronic components may exceed an allowable upper limit temperature thereby causing a malfunction or a failure. Thus, there has been a demand for a cooling method that is capable of sufficiently cooling the electronic components having a large heating value even when the electronic components are mounted with high density.

As one of the cooling methods, it has been suggested to immerse the electronic components in a refrigerant so as to cool the electronic components.

When the electronic components are disposed with high density, a refrigerant may not sufficiently flow between the electronic components, and thus, it becomes difficult to sufficiently cool each of the electronic components.

The followings are reference documents.

### [Document 1] Japanese Laid-Open Patent Publication No. 2011-518395 and

### [Document 2] Japanese Laid-Open Patent Publication No. 05-267515.

### SUMMARY

According to an aspect of the embodiments, an electronic equipment includes: a refrigerant tank that contains a refrigerant; a plurality of electronic components immersed in the refrigerant of the refrigerant tank; and a refrigerant injection member including a plurality of injection holes to inject the refrigerant supplied from a refrigerant inlet so as to cause the refrigerant to flow between the plurality of electronic components, wherein opening areas of the injection holes of the refrigerant injection member are set to be larger as the injection holes are far from the refrigerant inlet.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic view illustrating an exemplary liquid immersion cooling type electronic equipment;

FIG. 2 is a schematic view illustrating a configuration of an electronic equipment according to a first embodiment;

FIG. 3 is a perspective view illustrating electronic components, a circuit board, and a distributor;

FIG. 4 is a perspective view illustrating the distributor;

FIG. 5 is an enlarged view illustrating a portion of the distributor;

FIG. 6 is a view illustrating a relationship between positions and calibers of injection holes of the distributor;

FIG. 7 is a perspective view illustrating a distributor of Modification 1;

FIGS. 8A and 8B are schematic views illustrating a dummy of Modification 2;

FIG. 9 is a schematic view illustrating a configuration of an electronic equipment according to a second embodiment;

FIG. 10 is a perspective view of disk enclosures; and

FIG. 11 is a view illustrating an exemplary method of determining the calibers of the injection holes.

### DESCRIPTION OF EMBODIMENTS

Hereinafter, prior to describing embodiments, preliminary matters for facilitating the understanding of the embodiments will be described.

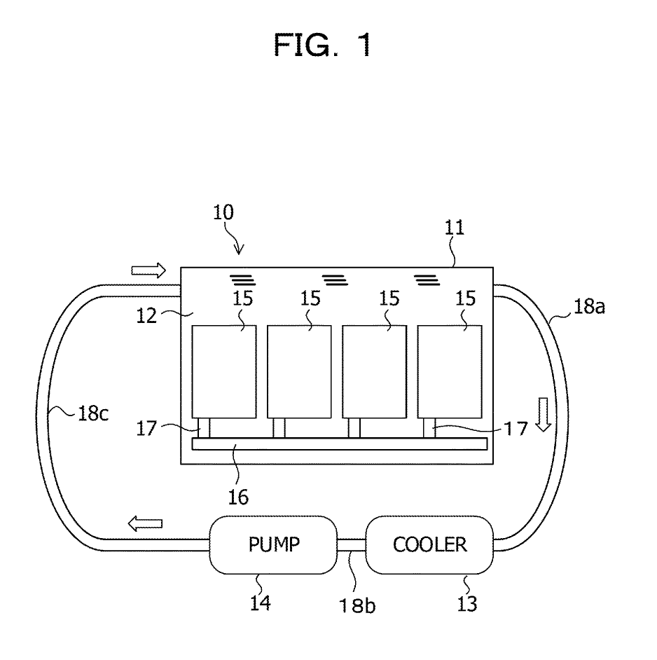

FIG. 1 is a schematic view illustrating an exemplary liquid immersion cooling type electronic equipment. Here, descriptions will be made on a case where electronic components are hard disks.

As illustrated in FIG. 1, an electronic equipment 10 includes a refrigerant tank 11 for containing a refrigerant 12, a cooler 13 for cooling the refrigerant 12, and a pump 14 for circulating the refrigerant 12 between the refrigerant tank 11 and the cooler 13.

A plurality of electronic components (hard disks) 15 is arranged in a state of being immersed in the refrigerant 12 inside the refrigerant tank 11. The electronic components 15 are electrically connected to a circuit board (a backplane or a midplane) disposed on the bottom portion of the refrigerant tank 11, through connectors 17.

The refrigerant outlet of the refrigerant tank 11 and the refrigerant inlet of the cooler 13 are interconnected by a pipe 18a. The refrigerant outlet of the cooler 13 and the suction opening of the pump 14 are interconnected by a pipe 18b. The ejection opening (delivery) of the pump 14 and the refrigerant inlet of the refrigerant tank 11 are interconnected by a pipe 17c. The arrow in FIG. 1 indicates the movement direction of the refrigerant 12.

In the electronic equipment 10 illustrated in FIG. 1, the refrigerant 12 flows from one side of the refrigerant tank 11 to the other side thereof. However, when the electronic components 15 are arranged with the high density, the refrigerant 12 does not sufficiently flow between the electronic components 15, and high temperature portions occur thereby causing a failure or a malfunction.

In the following embodiments, descriptions will be made on a liquid immersion cooling type electronic equipment capable of sufficiently cooling the electronic components arranged with the high density.

### First Embodiment

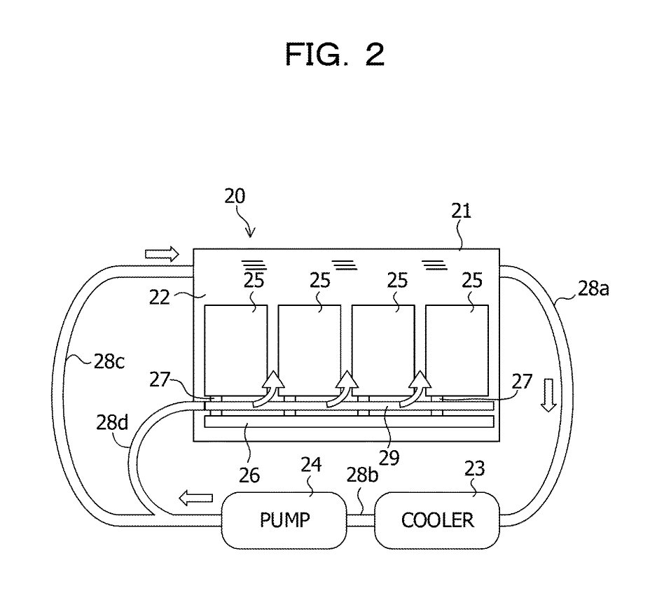

FIG. 2 is a schematic view illustrating a configuration of an electronic equipment according to a first embodiment. In the present embodiment as well, descriptions will be made on the case where electronic components are hard disks.

As illustrated in FIG. 2, an electronic equipment 20 according to the present embodiment includes a refrigerant tank 21 for containing a refrigerant 22, a cooler 23 for cooling the refrigerant 22, and a pump 24 for circulating the refrigerant 22 between the refrigerant tank 21 and the cooler 23. The arrow in FIG. 2 indicates the movement direction of the refrigerant 22. For example, an air or water cooling type chiller may be used as the cooler 23.

A plurality of electronic components (hard disks) 25 is arranged in a state of being immersed in the refrigerant 22 inside the refrigerant tank 21. The electronic components 25 are electrically connected to a circuit board (a backplane or a midplane) 26 disposed on the bottom portion of the refrigerant tank 21, through connectors 27. Further, a plate shaped distributor 29 is disposed between the circuit board 26 and the electronic components 25.

The refrigerant outlet of the refrigerant tank 21 and the refrigerant inlet of the cooler 23 are interconnected by a pipe 18a. The refrigerant outlet of the cooler 23 and the suction opening of the pump 24 are interconnected by a pipe 28b, and the ejection opening (delivery) of the pump 14 and the refrigerant inlet of the refrigerant tank 21 are interconnected by a pipe 28c. In addition, a pipe 28d is branched from the pipe 28c and connected to the distributer 29 inside the refrigerant tank 21. The distributer 29 is an exemplary refrigerant injection member.

For example, an insulating inert liquid such as hydrofluoroether is used as the refrigerant 22. Since the inert liquid has an insulating property, problems such as a short circuit do not occur even when, for example, conductors of the circuit board 16 or the connectors 27 are in contact with the refrigerant 22. In addition, the insulating inert liquid that may be used as the refrigerant 22 is not limited to the fluorine-based liquid.

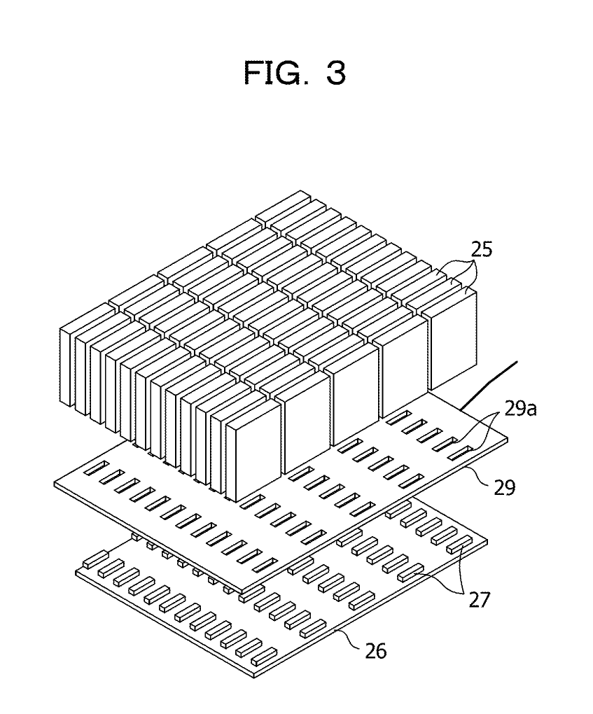

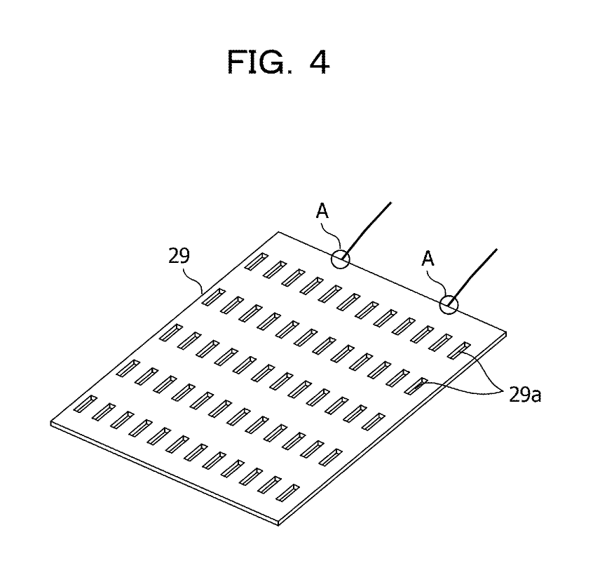

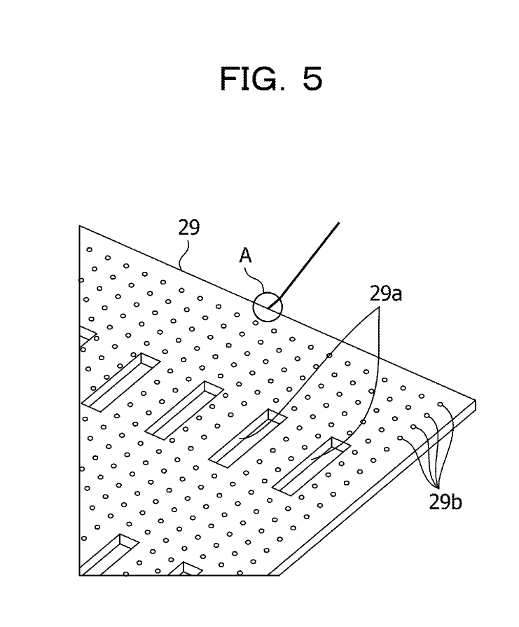

FIG. 3 is a perspective view illustrating the electronic components 25, the circuit board 26, and the distributor 29. FIG. 4 is a perspective view illustrating the distributor 29. FIG. 5 is an enlarged view illustrating a portion of the distributor 29.

As illustrated in FIG. 3, the connectors 27 for the connection to the electronic components 25 are arranged on the circuit board 26 at constant intervals in the width direction and the longitudinal direction of the circuit board 26. Holes 29a are formed at the portions of the distributor 29 corresponding to the connectors 27 such that the connectors 27 are inserted through the holes 29a. In addition, a refrigerant is supplied to the distributor 29 through the pipe 28d.

The inside of the distributor 29 is hollow, and a plurality of injection holes 29b is provided on the top surface of the distributor 29 such that the refrigerant 22 entering through the refrigerant inlet (represented by A in FIGS. 4 and 5) is injected therethrough. The refrigerant 22 is injected among the electronic components 25 from the injection holes 29b.

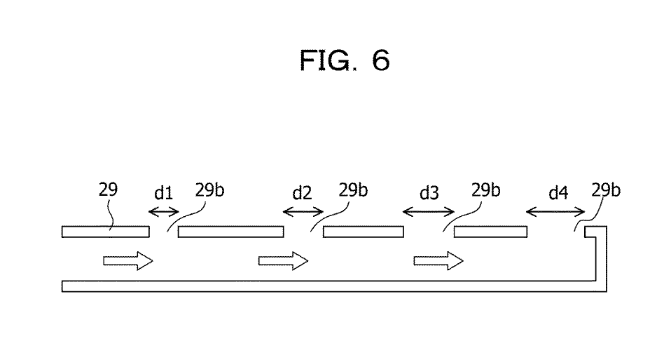

Here, when the calibers (the opening areas) of all the injection holes 29b are the same, the injection amount of the refrigerant 22 is reduced as the injection holes 29b are far from the refrigerant inlet, due to a pressure loss when the refrigerant 22 passes through the internal space of the distributor 29. Accordingly, in the present embodiment, as illustrated in FIG. 6, the calibers d₁, d₂, d₃, . . . are made large as the injection holes 29b are far from the refrigerant inlet of the distributor 29 so as to implement the uniformity of the injection amount of the refrigerant 22 to be injected from the respective injection holes 29b.

As described above, in the present embodiment, the distributor 29 is disposed between the electronic components 25 immersed in the refrigerant 22 inside the refrigerant tank 21 and the circuit board 26, and the refrigerant 22 is injected between the electronic components 25 from the injection holes 29b of the distributor 29. Accordingly, the refrigerant 22 may reliably flow between the electronic components 25 even when the electronic components 25 are arranged with the high density.

In addition, in the present embodiment, the calibers of the injection holes 29b of the distributor 29 are changed depending on the distance from the refrigerant inlet. Therefore, the amount of the refrigerant 22 to be injected from the respective injection holes 29b becomes uniform.

With these configurations, in the present embodiment, the respective electronic components 25 may be appropriately cooled even when the electronic components 25 are arranged with the high density.

### Modification 1

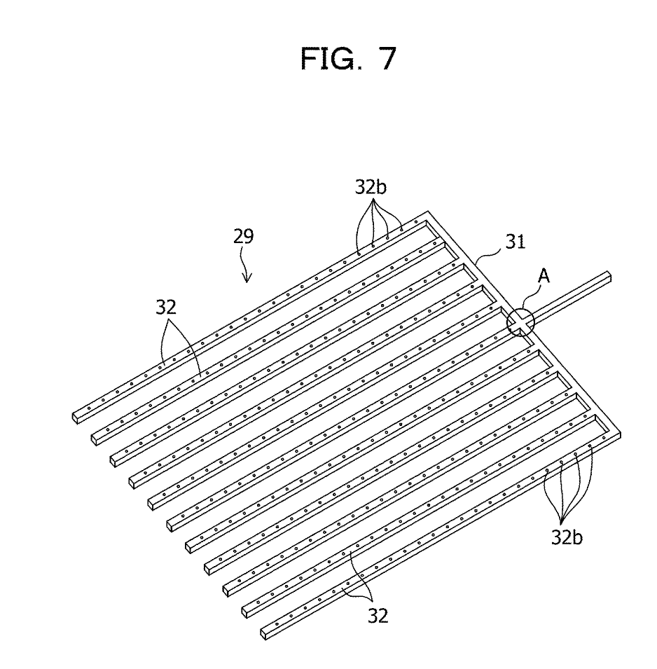

In the above-described first embodiment, the distributor 29 is a plate-shaped member of which the internal space is hollow. However, as illustrated in FIG. 7, the distributor 29 may have a structure including a main pipe 31 having a refrigerant inlet and branched pipes 32 branched from the main pipe 31 and provided with injection holes 32b.

In Modification 1 as well, the calibers (the opening areas) of the injection holes 32b are made large as the injection holes 32b are far from the refrigerant inlet (represented by A in FIG. 7) of the distributor 29. In Modification 1 as well, the same effects as described above may be obtained.

### Modification 2

In the first embodiment, the electronic components (hard disks) 25 are connected to all the connectors 27 of the circuit board 26. However, the electronic components 25 may not be connected to all the connectors 27 of the circuit board 26. In that case, dummies having almost the same shape as the electronic components 25 are generally connected to the connectors 27 to which the electronic components 25 are not connected.

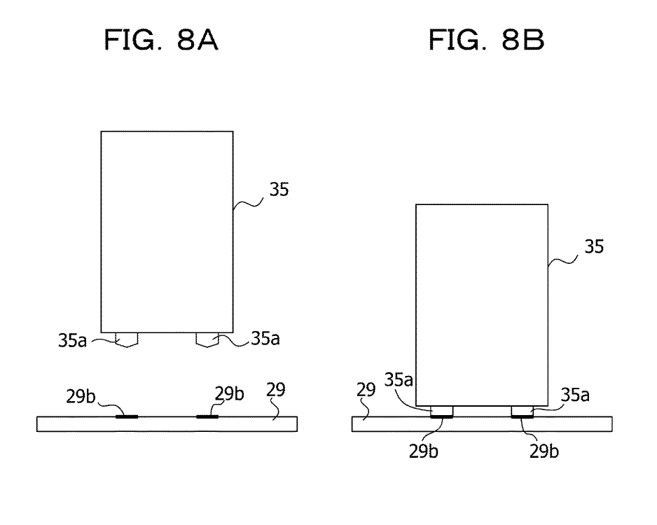

In Modification 2, as illustrated in FIGS. 8A and 8B, a dummy 35 is provided with closing units 35a to close the injection holes 29b of the distributor 29. Accordingly, the waste of a refrigerant which is supplied to the portions where no electronic components 25 are mounted may be eliminated.

### Second Embodiment

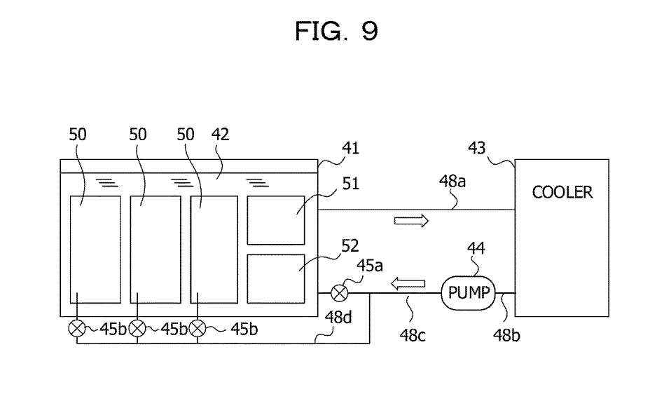

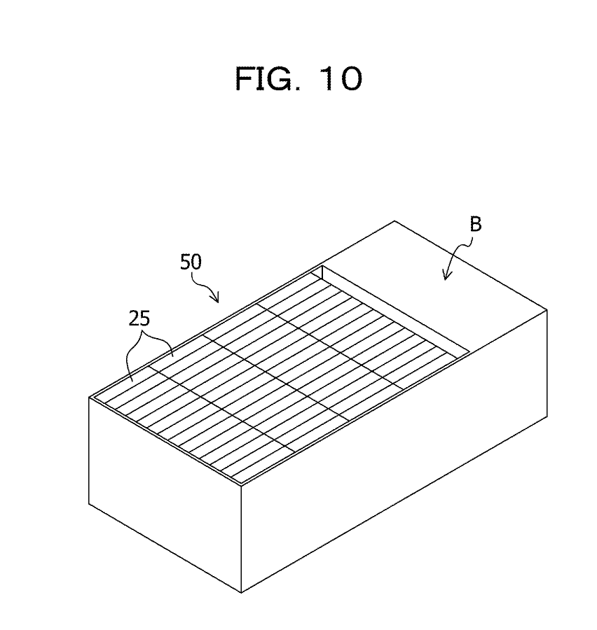

FIG. 9 is a schematic view illustrating a configuration of an electronic equipment according to a second embodiment. FIG. 10 is a perspective view of disk enclosures.

As illustrated in FIG. 9, an electronic equipment 40 according to the present embodiment includes a refrigerant tank 41 for containing a refrigerant 42, a cooler 43 for cooling the refrigerant 42, and a pump 44 for circulating the refrigerant 42 between the refrigerant tank 41 and the cooler 43. Further, a plurality of disk enclosures 50, a server 51, and a network switch 52 are arranged inside the refrigerant tank 41.

The refrigerant outlet of the refrigerant tank 41 and the refrigerant inlet of the cooler 43 are interconnected by a pipe 48a. The refrigerant outlet of the cooler 43 and the suction opening of a pump 44 are interconnected by a pipe 48b. A flow rate control valve 45a is connected to the refrigerant inlet of the refrigerant tank 41, and the valve 45a and the ejection opening of the pump 44 are interconnected by a pipe 48c.

As illustrated in FIG. 10, in each disk enclosure 50, a plurality of electronic components (hard disks) 25 is arranged in a state of being immersed in the refrigerant 42. As illustrated in FIG. 3, the electronic components 25 are electrically connected to the circuit board 26 through the connectors 27. In addition, the distributor 29 provided with the injection holes 29b is disposed between the electronic components 25 and the circuit board 26.

A flow rate control valve 45b is provided in each disk enclosure 50. One end of the valve 45b is connected to a pipe 48d branched from the pipe 48c, and the other end thereof is connected to the distributor 29 of each disk enclosure 50 (see, e.g., FIG. 3).

In addition, the electrical connection between the server 51 and the circuit board 26, and the electrical connection between the server 51 and the network switch 52 are implemented by predetermined cables (not illustrated), respectively. In addition, a power supply and a control circuit are disposed inside the portion indicated by the arrow B in FIG. 10 so as to drive the electronic components (hard disks) 25.

In the present embodiment as well, the distributor 29 is provided with the plurality of injection holes 29b, and the calibers of the injection holes 29b are set to be large as the injection holes 29b are far from the refrigerant inlet, as in the first embodiment.

In the first embodiment, only the electronic components 25 are immersed in the refrigerant 22. In contrast, in the second embodiment, the server 51, the network switch 52, and others are also immersed in the refrigerant 42 so as to cool the server 51, the network switch 52 and others simultaneously with the electronic components (hard disks) 25.

In the present embodiment as well, the distributor 29 is disposed between the electronic components 25 and the circuit board 26, and the refrigerant 22 is injected between the electronic components 25 from the injection holes 29b of the distributor 29. In addition, in order to unify the amount of the refrigerant 22 injected from the respective injection holes 29b, the calibers of the injection holes 29b of the distributor 29 are changed depending on the distance from the refrigerant inlet of the distributor 29.

With these configurations, in the present embodiment as well, the effect on appropriately cooling the electronic components 25 arranged with the high density is achieved.

### Example of Method of Determining Calibers of Injection Holes

Here, descriptions will be made on an exemplary method of determining the calibers of the injection holes. For simplification of descriptions, the number of the injection holes is set to four (4).

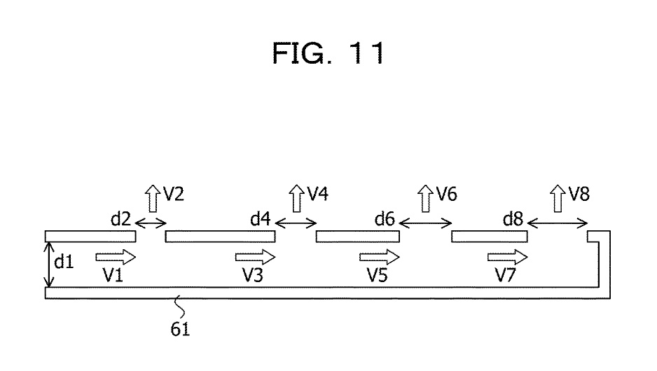

For example, as illustrated in FIG. 11, a diameter of a pipe 61 is set to d₁, and diameters of the respective injection holes are set to d₂, d₄, d₆, and d₈ in this order from the refrigerant inlet side. In addition, a flow rate of the refrigerant at the inlet of the pipe 61 is V₁, and flow rates of the refrigerant injected from the respective injection holes are set to V₂, V₄, V₆, and V₈ in this order from that closest to the inlet. In addition, flow rates of the refrigerant between the respective injection holes inside the pipe 61 are set to V₃, V₅, and V₇, as illustrated in FIG. 11.

In this case, since the flow rate of the refrigerant introduced from the inlet of the pipe 61 is the same as the sum of the flow rates of the refrigerant injected from the respective injection holes, the following equation (1) is established.

d₁²V₁=d₂²V₂+d₄²V₄+d₆²V₆+d₈²V₈ (1)

In addition, since the flow rates of the refrigerant injected from the respective injection holes 29b are the same, the following equation (2) is established.

(d₁²V₁)/4=d₂²V₂=d₄²V₄=d₆²V₆=d₈²V₈=d₇²V₇ (2)

Since the flow rates of the refrigerant are kept before and after the respective branch points, the following equation (3) is established.

d₁²V₁=d₁²V₃+d₂²V₂ (3)

When the equation (2) is applied to the equation (3), the following equation (4) is established.

d₁²V₃=(3/4)×d₁²V₁ (4)

Similarly, the following equations are established.

d₁²V₅=(1/2)×d₁²V₁

d₁²V₇=(3/4)×d₁²V₁

Here, when mₓ is a mass of a fluid flowing in the cross section of the pipe at a flow rate Vₓ, the following equations (5) are established.

m₁=n(d₁/2)²V₁,

m₂=n(d₂/2)²V₂,

. . . ,

mₓ=n(dₓ/2)²Vₓ (5)

Here, in consideration of an energy relation at the branch point closest to the inlet, the relation represented in the following equation (6) is established.

(1/2)m₁V₁²−(1/4)m₂V₂²−(1/2)m₃V₃²=mgΔh (6)

Here, Δh is a loss head at the branch point. In addition, d₁=0.015 (m), V₁=1 (m/s), an equivalent pipe length of the flow path curved perpendicularly from the branch point L₁=0.9 (m), and an equivalent pipe length of the flow path extending straight from the branch point L₂=0.18 (m).

In the Darcy-Weisbach equation,

Δh=(λL/d)V²/(2g) (7)

Here, g is the acceleration of gravity. When the equations (2), (5), (6), and (7) are reorganized assuming that a pipe friction coefficient λ=0.03, the following equations (8) are obtained.

V₁=0.621(m/s)

d₂=0.00952(m) (8)

Likewise, when the equations are reorganized by establishing energy relation equations for the respective branch points, the following equations (9) are obtained.

V₄=0.600 . . . (m/s)

d₄=0.00968 . . . (m)

V₆=0.286 . . . (m/s)

d₆=0.0140 . . . (m)

V₈=0.169 . . . (m/s)

d₈=0.0183 . . . (m) (9)

However, with respect to V8 and d8, the corresponding portion is regarded as an 90° elbow rather than a branched pipe, and it is assumed that an equivalent pipe length thereof L3=0.6 (m).

In view of this point, when d₁=9.5 mm, d₂=9.7 mm, d₃=14.0 mm, and d₄=18.3 mm, the flow rates of the refrigerant injected from the respective injection holes become the same. Here, while the flow rate of the refrigerant at the inlet is V₁=1 (m/s), the calibers of the injection holes become constant, regardless of V₁.

All examples and conditional language recited herein are intended for pedagogical purposes to aiding the reader in understanding the invention and the concepts contributed by the inventor to furthering the art, and are not to be construed as limitation to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic equipment comprising:
a refrigerant tank that contains a refrigerant;
a plurality of electronic components immersed in the refrigerant of the refrigerant tank; and
a refrigerant injection member including a plurality of injection holes to inject the refrigerant supplied from a refrigerant inlet so as to cause the refrigerant to flow between the plurality of electronic components,
wherein opening areas of the injection holes of the refrigerant injection member are set to be larger as the injection holes are far from the refrigerant inlet.

2. The electronic equipment according to claim 1, further comprising:
a circuit board disposed inside the refrigerant tank to be electrically connected to the electronic components,
wherein the refrigerant injection member is disposed between the circuit board and the electronic components.

3. The electronic equipment according to claim 1, wherein at least one of the electronic components is a storage device.

4. The electronic equipment according to claim 1, wherein the refrigerant is an insulating inert liquid.

5. The electronic equipment according to claim 1, further comprising:
a dummy disposed in the refrigerant together with the electronic components, and including a closing unit configured to close the injection holes.
